(19) United States
(12) Patent Application Publication
(10) Pub. No.: US 2026/0271767 A1
(43) Pub. Date: Sep. 10, 2026

(54) SEMICONDUCTOR DEVICE

(71) Applicant: ROHM CO., LTD., Kyoto (JP)

(72) Inventor: Tomohira KIKUCHI, Kyoto (JP)

(21) Appl. No.: 19/551,854

(22) Filed: Feb. 27, 2026

(30) Foreign Application Priority Data
Mar. 6, 2025 (JP) 2025-035637

(51) Int. Cl. H10W 72/50; H10W 70/40; H10W 74/00; H10W 90/00

(52) U.S. Cl. CPC H10W 72/5366; H10W 70/421; H10W 72/537; H10W 74/00; H10W 90/756

(57) ABSTRACT

A semiconductor device includes: a first die pad having a first mounting surface facing one side in a first direction; a first semiconductor element including a first electrode located on an opposite side of the one side in the first direction; a plurality of first leads each having a first connection surface facing the one side in the first direction; and a first wire conductively joined to the first electrode and the first connection surface of one of the plurality of first leads. The first wire includes first and second connection portions and first to third bent portions. Each of the first and second bent portions has a convex shape facing toward the side moving away from the first mounting surface, and the third bent portion has a convex shape facing toward the side approaching the first mounting surface.

### CROSS-REFERENCE TO RELATED APPLICATION

This application is based upon and claims the benefit of priority from Japanese Patent Application No. 2025-035637, filed on March 6, 2025, the entire contents of which are incorporated herein by reference.

### TECHNICAL FIELD

The present disclosure relates to a semiconductor device.

### BACKGROUND

A semiconductor device known in the related art includes a first die pad, a second die pad, a control element (controller) and a drive element (gate driver) mounted on the first die pad and the second die pad, respectively, and a sealing resin that covers the first die pad, the second die pad, the control element and the drive element. The semiconductor device drives a switching element such as an IGBT or a MOSFET. The semiconductor device is used in an inverter circuit, etc.

The semiconductor device further includes a first lead (first side terminal) located near the first die pad and a first bonding wire conductively joined to the control element and the first lead. During the manufacture of the semiconductor device, the first lead is displaced in a thickness direction relative to the first die pad. When such a displacement is increased, the first bonding wire conductively joined to the first lead may be broken.

### BRIEF DESCRIPTION OF DRAWINGS

The accompanying drawings, which are incorporated in and constitute a part of the specification, illustrate embodiments of the present disclosure.

FIG. 1 is a plan view of a semiconductor device according to a first embodiment of the present disclosure.

FIG. 2 is a plan view corresponding to FIG. 1, which is shown through a sealing resin.

FIG. 3 is a front view of the semiconductor device shown in FIG. 1.

FIG. 4 is a rear view of the semiconductor device shown in FIG. 1.

FIG. 5 is a left side view of the semiconductor device shown in FIG. 1.

FIG. 6 is a right side view of the semiconductor device shown in FIG. 1.

FIG. 7 is a cross-sectional view taken along line VII-VII in FIG. 2.

FIG. 8 is a cross-sectional view taken along line VIII-VIII in FIG. 2.

FIG. 9 is a cross-sectional view taken along line IX-IX in FIG. 2.

FIG. 10 is a partially enlarged view of the semiconductor device shown in FIG. 2, and shows a first semiconductor element and its surrounding area.

FIG. 11 is a cross-sectional view taken along line XI-XI in FIG. 10.

FIG. 12 is a cross-sectional view taken along line XII-XII in FIG. 10.

FIG. 13 is a partially enlarged view of the semiconductor device shown in FIG. 2, and shows a second semiconductor element and its surrounding area.

FIG. 14 is a cross-sectional view taken along line XIV-XIV in FIG. 13.

FIG. 15 is a cross-sectional view taken along line XV-XV in FIG. 13.

FIG. 16 is a partially enlarged plan view of a semiconductor device according to a second embodiment of the present disclosure, and corresponds to FIG. 10.

FIG. 17 is a cross-sectional view taken along line XVII-XVII in FIG. 16.

FIG. 18 is a plan view of a semiconductor device according to a third embodiment of the present disclosure, which is shown through a sealing resin.

FIG. 19 is a plan view of a semiconductor device according to a fourth embodiment of the present disclosure, which is shown through a sealing resin.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

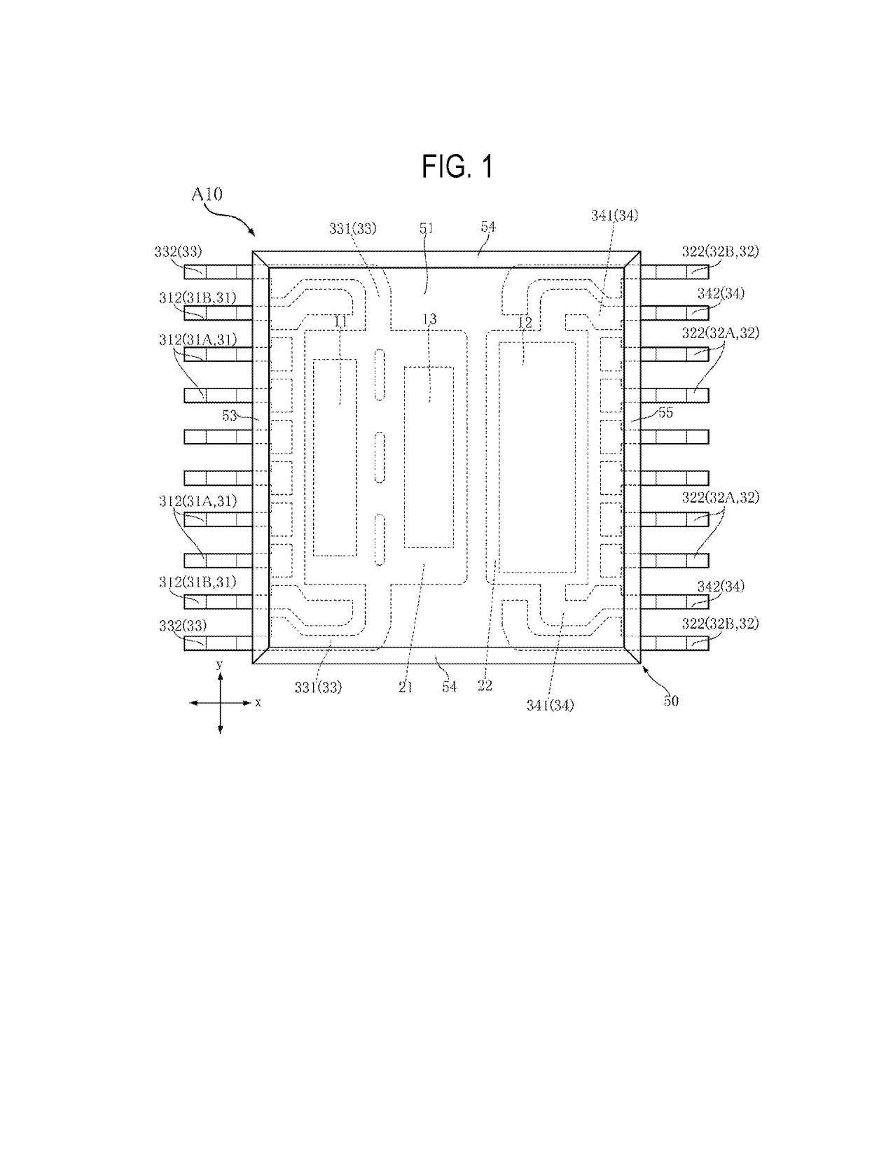

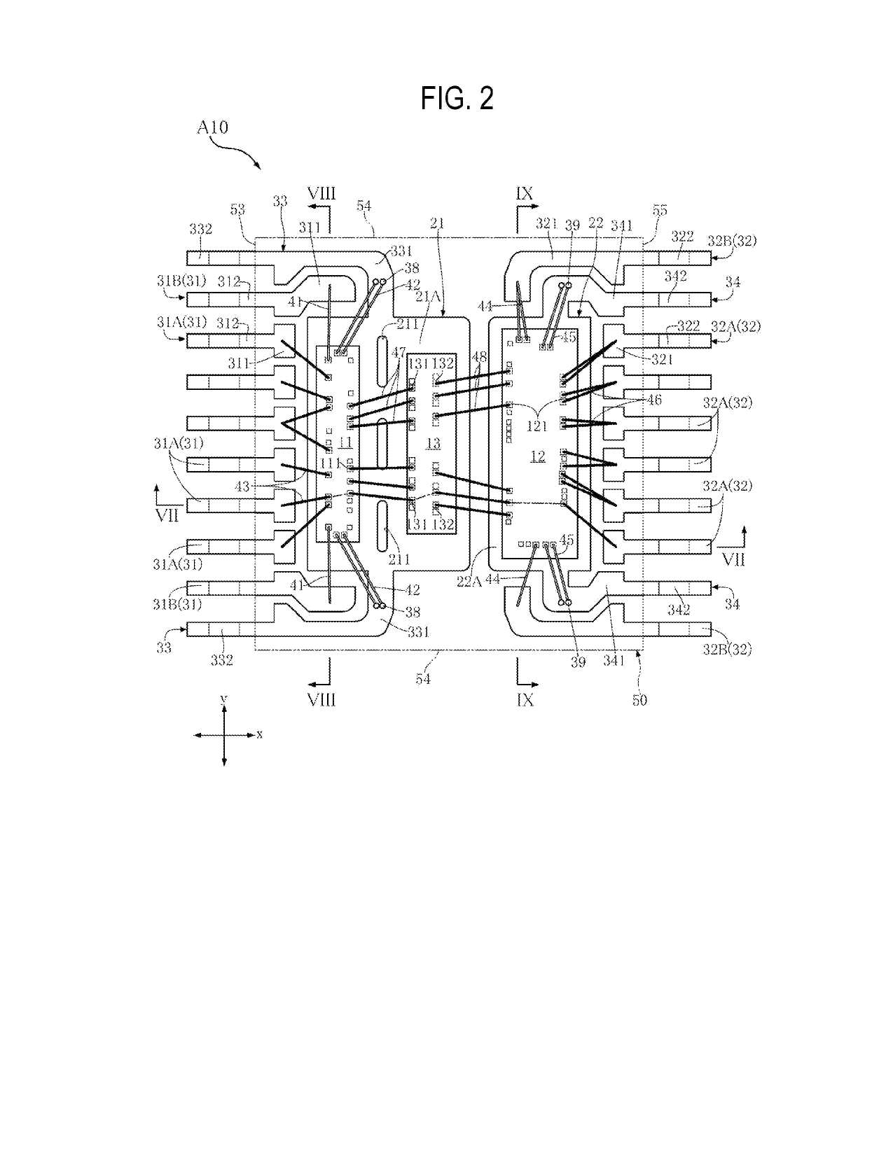

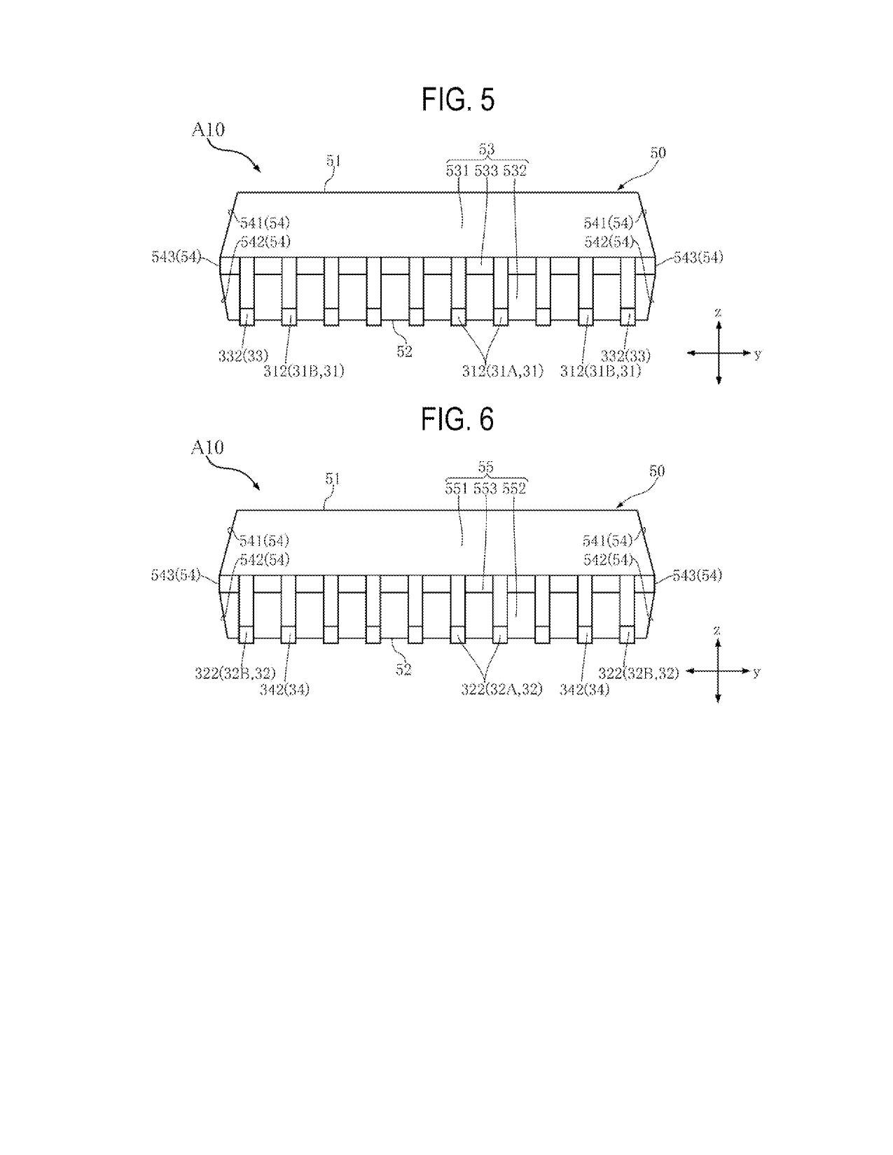

A semiconductor device A10 according to a first embodiment of the present disclosure will be described with reference to FIGS. 1 to 15. The semiconductor device A10 includes a first semiconductor element 11, a second semiconductor element 12, an insulating element 13, a first die pad 21, a second die pad 22, a plurality of first leads 31, a plurality of second leads 32, two first suspension leads 33, two second suspension leads 34, and a sealing resin 50. The semiconductor device A10 further includes a plurality of first wires 41, a plurality of second wires 42, a plurality of third wires 43, a plurality of fourth wires 44, a plurality of fifth wires 45, a plurality of sixth wires 46, a plurality of seventh wires 47, a plurality of eighth wires 48, a plurality of first bumps 38, and a plurality of second bumps 39. The semiconductor device A10 is surface-mounted on, for example, a wiring board of an inverter device for an electric vehicle, a hybrid vehicle, or the like. The semiconductor device A10 is packaged in a small outline package (SOP) format. However, the package format of the semiconductor device A10 is not limited to the SOP. For ease of understanding, FIG. 2 shows the sealing resin 50 as being transparent. In FIG. 2, an outline of the sealing resin 50 is indicated by an imaginary line (two-dot chain line).

In the description of the semiconductor device A10, for the sake of convenience in description, a normal direction to a first mounting surface 21A of the first die pad 21 (described later) will be referred to as a "first direction z." A direction perpendicular to the first direction z will be referred to as a "second direction x." A direction perpendicular to the first direction z and the second direction x will be referred to as a "third direction y."

In the semiconductor device A10, the first semiconductor element 11, the second semiconductor element 12, and the insulating element 13 are respectively composed of individual elements. The second semiconductor element 12 is located on a side of the insulating element 13 opposite the first semiconductor element 11 in the second direction x. The insulating element 13 is located near the first semiconductor element 11 in the third direction y. When viewed in the first direction z, each of the first semiconductor element 11, the second semiconductor element 12, and the insulating element 13 has a rectangular shape with a long side extending in the third direction y.

The first semiconductor element 11 controls the second semiconductor element 12. The first semiconductor element 11 includes a circuit that converts an electrical signal input from a semiconductor device other than the semiconductor device A10 into a PWM (pulse width modulation) control signal, a transmitting circuit that transmits the PWM control signal to the second semiconductor element 12, and a receiving circuit that receives the electrical signal from the second semiconductor element 12.

The second semiconductor element 12 drives a switching element located outside the semiconductor device A10. The switching element is, for example, an insulated gate bipolar transistor (IGBT) or a metal-oxide-semiconductor field-effect transistor (MOSFET). The second semiconductor element 12 includes a receiving circuit for receiving a PWM control signal, a circuit for driving the switching element based on the PWM control signal, and a transmitting circuit for transmitting an electrical signal to the first semiconductor element 11. An example of the electrical signal is an output signal from a temperature sensor located near a motor.

The insulating element 13 transmits electrical signals, such as the PWM control signal and the like, in an insulated state. The insulating element 13 is of an inductor-coupled type. An example of the inductor-coupled type insulating element 13 is an insulating transformer. The insulating transformer transmits the electrical signals in an insulated state by inductively coupling two inductors (coils). The two inductors include a transmission-side inductor and a reception-side inductor. Each of the two inductors is stacked one above the other in the first direction z. A dielectric layer made of silicon dioxide (SiO₂) or the like is located between the transmission-side inductor and the reception-side inductor. The dielectric layer electrically insulates the transmission-side inductor and the reception-side inductor from each other. Alternatively, the insulating element 13 may be of a capacitive type. An example of the capacitive type insulating element 13 is a capacitor.

Voltages applied to the first semiconductor element 11 and the second semiconductor element 12 are different from each other. As a result, a potential difference occurs between the first semiconductor element 11 and the second semiconductor element 12. In the semiconductor device A10, the voltage applied to the second semiconductor element 12 is higher than the voltage applied to the first semiconductor element 11. Additionally, in the semiconductor device A10, a power supply voltage supplied to the second semiconductor element 12 is higher than that supplied to the first semiconductor element 11.

Therefore, in the semiconductor device A10, a first circuit including the first semiconductor element 11 and a second circuit including the second semiconductor element 12 are insulated from each other by the insulating element 13. The insulating element 13 is electrically connected to the first circuit and the second circuit. The first circuit includes the first semiconductor element 11, the plurality of first leads 31, and the two first suspension leads 33. The second circuit includes the second die pad 22, the plurality of second leads 32, and the two second suspension leads 34. The first circuit and the second circuit have relatively different potentials. In the semiconductor device A10, a potential of the second circuit is higher than that of the first circuit. Further, the insulating element 13 relays mutual signals between the first circuit and the second circuit. For example, in the inverter device for the electric vehicle or the hybrid vehicle, the voltage applied to the ground (GND) of the first semiconductor element 11 is about 0 V, while the voltage applied to the ground of the second semiconductor element 12 may transiently become 600 V or higher.

As shown in FIGS. 2, 7 and 8, the first semiconductor element 11 includes a plurality of first electrodes 111. The plurality of first electrodes 111 are located on a side opposite the side facing the first die pad 21 in the first direction z. The plurality of first electrodes 111 contain, for example, aluminum (Al). The plurality of first electrodes 111 are electrically connected to a circuit formed in the first semiconductor element 11.

As shown in FIGS. 2, 7 and 9, the second semiconductor element 12 includes a plurality of second electrodes 121. The plurality of second electrodes 121 are located on a side opposite the side facing the second die pad 22 in the first direction z. The plurality of second electrodes 121 contain, for example, aluminum. The plurality of second electrodes 121 are electrically connected to a circuit formed in the second semiconductor element 12.

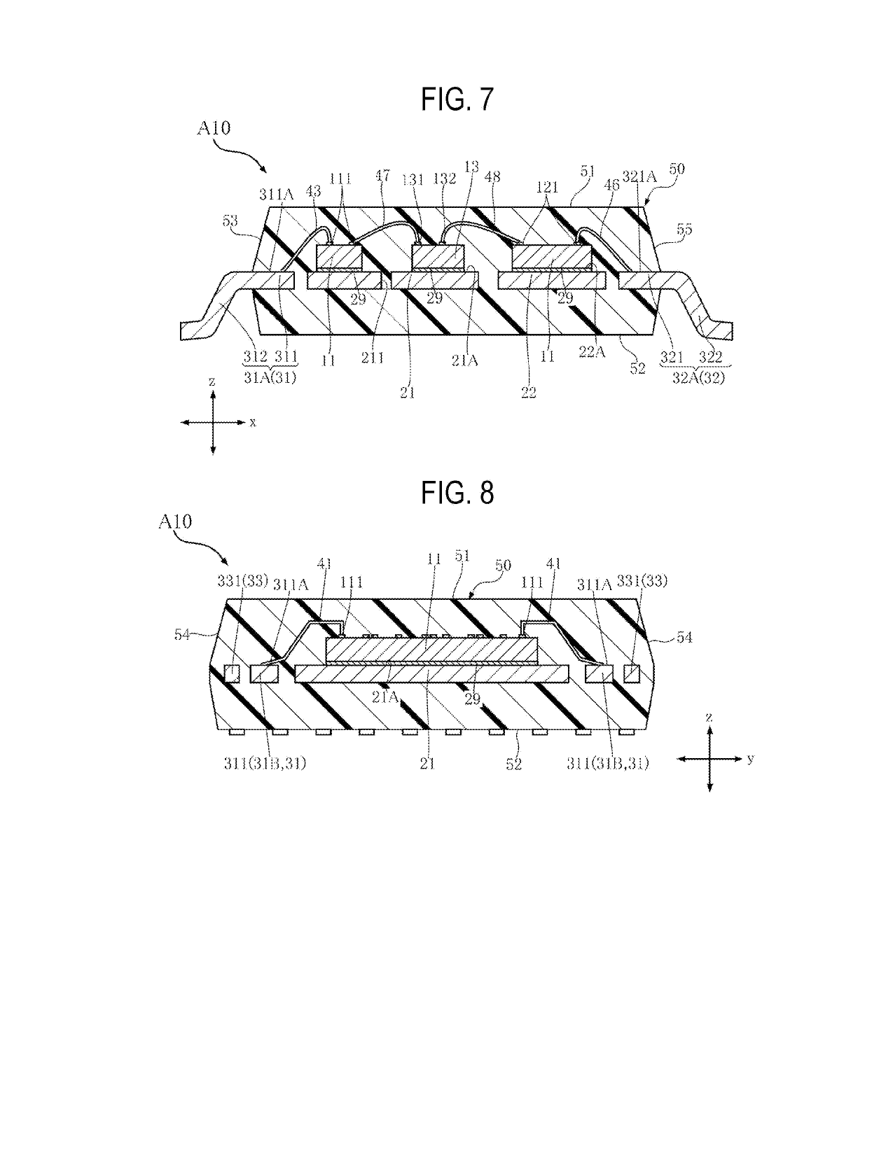

As shown in FIGS. 2 and 7, the insulating element 13 is located between the second semiconductor element 12 and the first semiconductor element 11 in the first direction z. Therefore, the first semiconductor element 11 is located on a side of the insulating element 13 opposite the second semiconductor element 12 in the second direction x. The insulating element 13 includes a plurality of third electrodes 131 and a plurality of fourth electrodes 132. The plurality of third electrodes 131 and the plurality of fourth electrodes 132 are located on a side of the insulating element 13 opposite the side facing the first die pad 21 in the first direction z. Each of the plurality of third electrodes 131 and the plurality of fourth electrodes 132 is electrically connected to either the transmission-side inductor or the reception-side inductor. The plurality of third electrodes 131 are arranged along the third direction y and are located between the first semiconductor element 11 and the second semiconductor element 12 in the second direction x. The plurality of fourth electrodes 132 are arranged along the third direction y and are located on a side of the plurality of third electrodes 131 opposite the first semiconductor element 11 in the second direction x. The plurality of third electrodes 131 and the plurality of fourth electrodes 132 contain, for example, aluminum.

As shown in FIG. 1, the sealing resin 50 covers the first semiconductor element 11, the second semiconductor element 12, the insulating element 13, the first die pad 21, and the second die pad 22. As shown in FIGS. 7 to 9, the sealing resin 50 further covers the first wires 41 to the seventh wires 47. The sealing resin 50 is an insulator. The sealing resin 50 is made of a material containing, for example, an epoxy resin. When viewed in the first direction z, the sealing resin 50 has a rectangular shape.

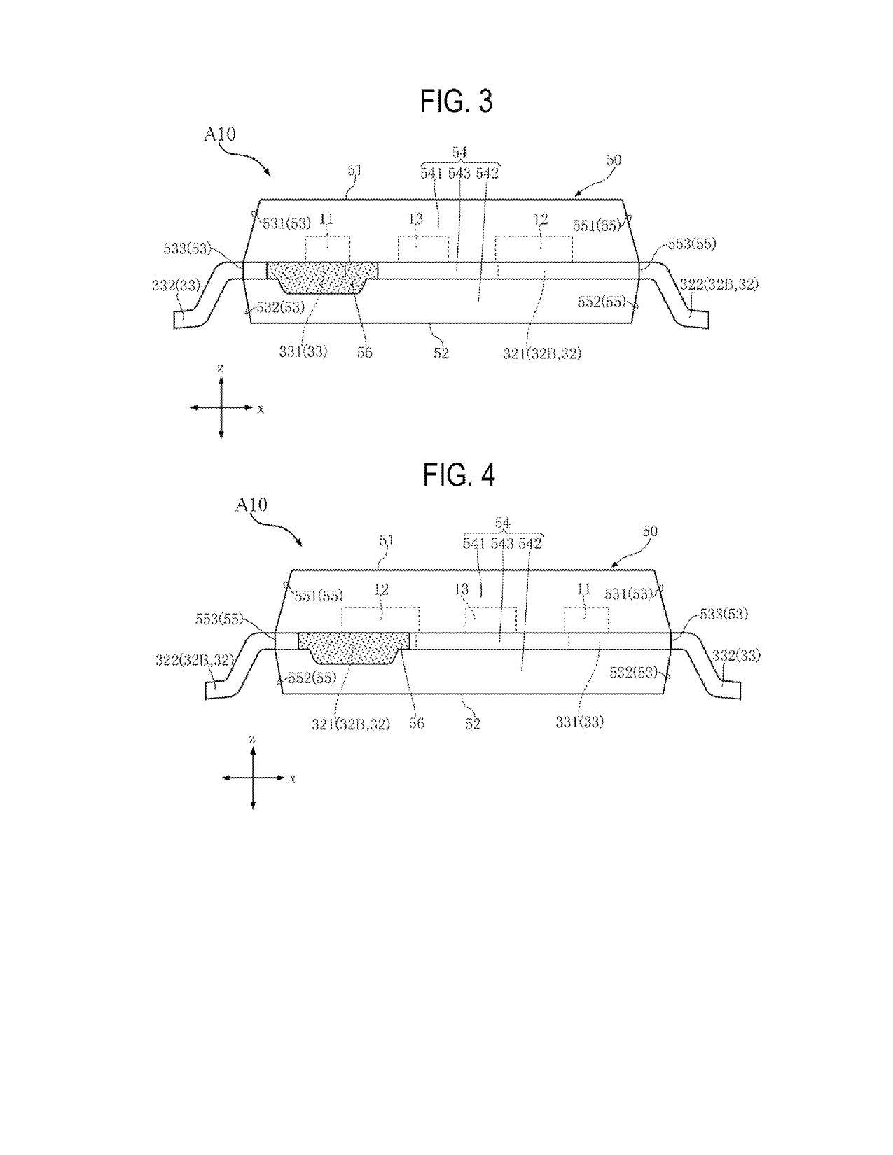

As shown in FIGS. 3 to 6, the sealing resin 50 has a top surface 51, a bottom surface 52, a first side surface 53, two second side surfaces 54, and a third side surface 55.

As shown in FIGS. 3 to 6, the top surface 51 and the bottom surface 52 face directions opposite to each other in the first direction z. The top surface 51 faces the same side as the first mounting surface 21A of the first die pad 21 in the first direction z, which will be described later.

As shown in FIGS. 3 to 5, the first side surface 53 is connected to the top surface 51 and the bottom surface 52, and faces one side in the second direction x. The first side surface 53 is located closer to the first die pad 21 than the third side surface 55. The first side surface 53 includes a first upper portion 531, a first lower portion 532, and a first intermediate portion 533. The first upper portion 531 is connected to the top surface 51 on one side in the first direction z and to the first intermediate portion 533 on the other side in the first direction z. The first upper portion 531 is inclined with respect to the top surface 51. The first lower portion 532 is connected to the bottom surface 52 on one side in the first direction z and to the first intermediate portion 533 on the other side in the first direction z. The first lower portion 532 is inclined with respect to the bottom surface 52. The first intermediate portion 533 is located between the first upper portion 531 and the first lower portion 532 in the first direction z. An in-plane direction of the first intermediate portion 533 includes the first direction z. When viewed in the first direction z, the first intermediate portion 533 is located outward from the top surface 51 and the bottom surface 52.

As shown in FIGS. 3 to 6, the two second side surfaces 54 are connected to the top surface 51 and the bottom surface 52, respectively, and face directions opposite to each other in the third direction y. Each of the two second side surfaces 54 includes a second upper portion 541, a second lower portion 542, and a second intermediate portion 543. One side of the second upper portion 541 in the first direction z is connected to the top surface 51, and the other side of the second upper portion 541 in the first direction z is connected to the second intermediate portion 543. The second upper portion 541 is inclined with respect to the top surface 51. One side of the second lower portion 542 in the first direction z is connected to the bottom surface 52, and the other side of the second lower portion 542 in the first direction z is connected to the second intermediate portion 543. The second lower portion 542 is inclined with respect to the bottom surface 52. The second intermediate portion 543 is located between the second upper portion 541 and the second lower portion 542 in the first direction z. An in-plane direction of the second intermediate portion 543 includes the first direction z. When viewed in the first direction z, the second intermediate portion 543 is located outward from the top surface 51 and the bottom surface 52.

As shown in FIGS. 3, 4 and 6, the third side surface 55 is connected to the top surface 51 and the bottom surface 52 and faces a direction opposite to the first side surface 53 in the second direction x. The third side surface 55 includes a third upper portion 551, a third lower portion 552, and a third intermediate portion 553. One side of the third upper portion 551 in the first direction z is connected to the top surface 51, and the other side of the third upper portion 551 in the first direction z is connected to the third intermediate portion 553. The third upper portion 551 is inclined with respect to the top surface 51. One side of the third lower portion 552 in the first direction z is connected to the bottom surface 52, and the other side of the third lower portion 552 in the first direction z is connected to the third intermediate portion 553. The third lower portion 552 is inclined with respect to the bottom surface 52. The third intermediate portion 553 is located between the third upper portion 551 and the third lower portion 552 in the first direction z. An in-plane direction of the third intermediate portion 553 includes the first direction z. When viewed in the first direction z, the third intermediate portion 553 is located outward from the top surface 51 and the bottom surface 52.

The first die pad 21, the second die pad 22, the plurality of first leads 31, the plurality of second leads 32, the two first suspension leads 33, and the two second suspension leads 34 contain copper (Cu). The first die pad 21, the second die pad 22, the plurality of first leads 31, the plurality of second leads 32, the two first suspension leads 33, and the two second suspension leads 34 are obtained from the same lead frame.

As shown in FIGS. 1 and 2, the first die pad 21 and the second die pad 22 are spaced apart from each other in the second direction x. In the semiconductor device A10, the first semiconductor element 11 and the insulating element 13 are mounted on the first die pad 21, and the second semiconductor element 12 is mounted on the second die pad 22. In this case, an area of the first die pad 21 is larger than that of the second die pad 22 when viewed in the first direction z.

As shown in FIGS. 7 and 8, the first die pad 21 has the first mounting surface 21A. The first mounting surface 21A faces the same side as the top surface 51 of the sealing resin 50 in the first direction z. Each of the first semiconductor element 11 and the insulating element 13 is joined to the first mounting surface 21A via a bonding layer 29. The bonding layer 29 is made of a paste containing metal particles. The metal particles are, for example, silver (Ag). Therefore, the bonding layer 29 is a conductor. Alternatively, the bonding layer 29 may be solder.

As shown in FIGS. 2 and 7, the first die pad 21 has a plurality of first through-holes 211. Each of the plurality of first through-holes 211 penetrates the first die pad 21 in the first direction z and extends in the third direction y. The plurality of first through-holes 211 are arranged along the third direction y. The plurality of first through-holes 211 are located between the first semiconductor element 11 and the insulating element 13 in the second direction x.

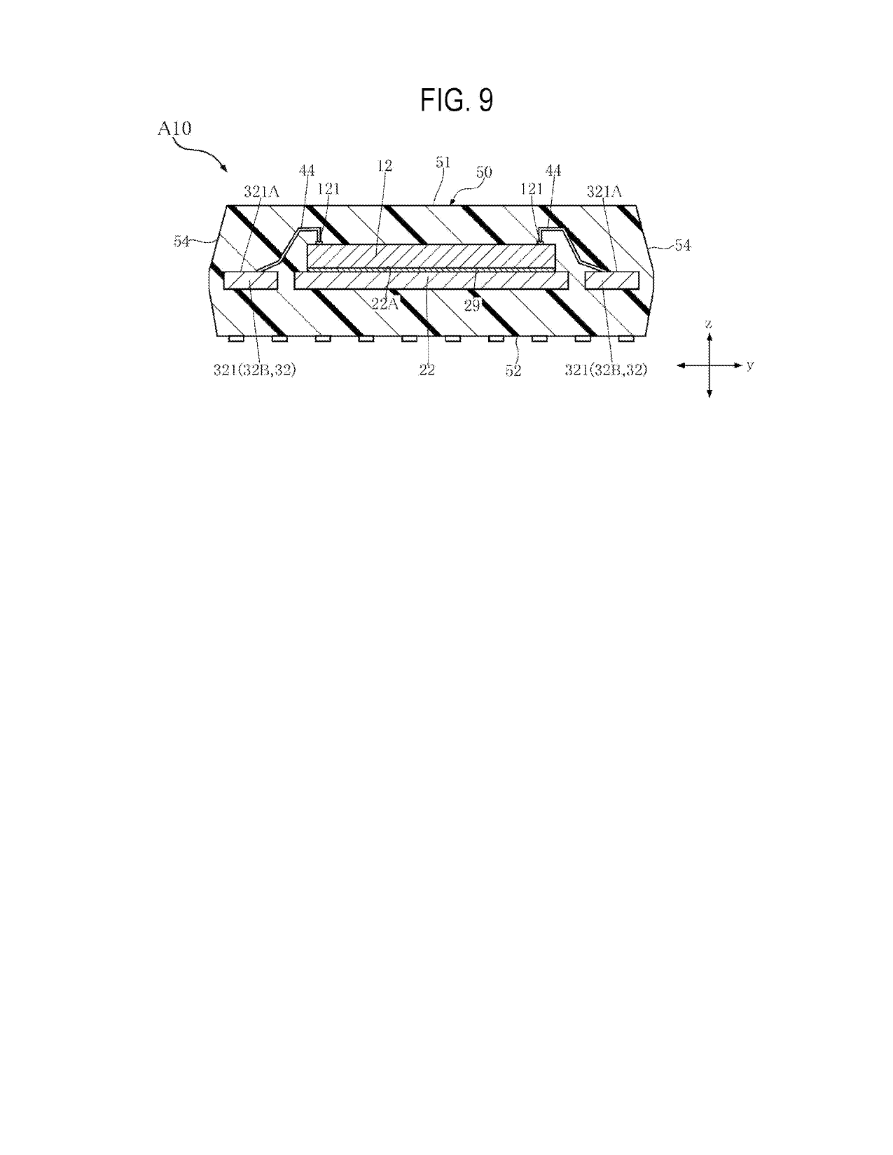

As shown in FIGS. 7 and 9, the second die pad 22 has a second mounting surface 22A. The second mounting surface 22A faces the same side as the first mounting surface 21A of the first die pad 21 in the first direction z. The second semiconductor element 12 is joined to the second mounting surface 22A via a bonding layer 29.

As shown in FIGS. 1 and 2, the plurality of first leads 31 are located closer to the first die pad 21 than to the second die pad 22 in the second direction x. The plurality of first leads 31 are arranged along the third direction y. At least one of the plurality of first leads 31 is electrically connected to the first semiconductor element 11.

As shown in FIGS. 2 and 7, each of the plurality of first leads 31 includes a first inner portion 311 and a first outer portion 312. The first inner portion 311 is covered with the sealing resin 50. As shown in FIG. 7, the first inner portion 311 has a first connection surface 311A. The first connection surface 311A faces the same side as the first mounting surface 21A of the first die pad 21 in the first direction z. The first connection surface 311A and the first mounting surface 21A are included in the same plane. The first outer portion 312 is connected to the first inner portion 311. The first outer portion 312 protrudes from the first intermediate portion 533 of the first side surface 53 of the sealing resin 50. When viewed in the first direction z, the first outer portion 312 extends in the second direction x. When viewed in the third direction y, the first outer portion 312 is bent in a gull-wing shape. The shape of the first outer portion 312 is the same as that of a third outer portion 332 (see FIGS. 3 and 4) of each of the two first suspension leads 33 described below. A surface of the first outer portion 312 is plated with, for example, tin.

As shown in FIG. 2, the plurality of first leads 31 include a plurality of first intermediate leads 31A and two first side leads 31B. The plurality of first intermediate leads 31A are located on a side of the first die pad 21 opposite the second die pad 22 in the second direction x. The two first side leads 31B are located individually on both sides of the plurality of first intermediate leads 31A in the third direction y. Each of the two first side leads 31B includes a portion located on either side of the first die pad 21 in the third direction y. A dimension in the second direction x of the first inner portion 311 of each of the two first side leads 31B is larger than that in the second direction x of the first inner portion 311 of each of the plurality of first intermediate leads 31A.

As shown in FIGS. 1 and 2, the two first suspension leads 33 are individually connected to both sides of the first die pad 21 in the third direction y. The two first suspension leads 33 are individually located on both sides of the plurality of first leads 31 in the third direction y. Each of the two first suspension leads 33 is spaced apart from two second side surfaces 54 of the sealing resin 50. Each of the two first suspension leads 33 has a third inner portion 331 and the third outer portion 332. The third inner portion 331 is connected to the first die pad 21 and is covered with the sealing resin 50. The third outer portion 332 is connected to the third inner portion 331. The third outer portion 332 protrudes from a first intermediate portion 533 of the first side surface 53 of the sealing resin 50. When viewed in the first direction z, the third outer portion 332 extends in the second direction x. As shown in FIGS. 3 and 4, the third outer portion 332 is bent in a gull-wing shape when viewed in the third direction y. A surface of the third outer portion 332 is plated with, for example, tin.

As shown in FIGS. 2 and 8, each of the plurality of first wires 41 is conductively joined to one of the plurality of first electrodes 111 of the first semiconductor element 11 and to the first connection surface 311A of one of the two first side leads 31B.

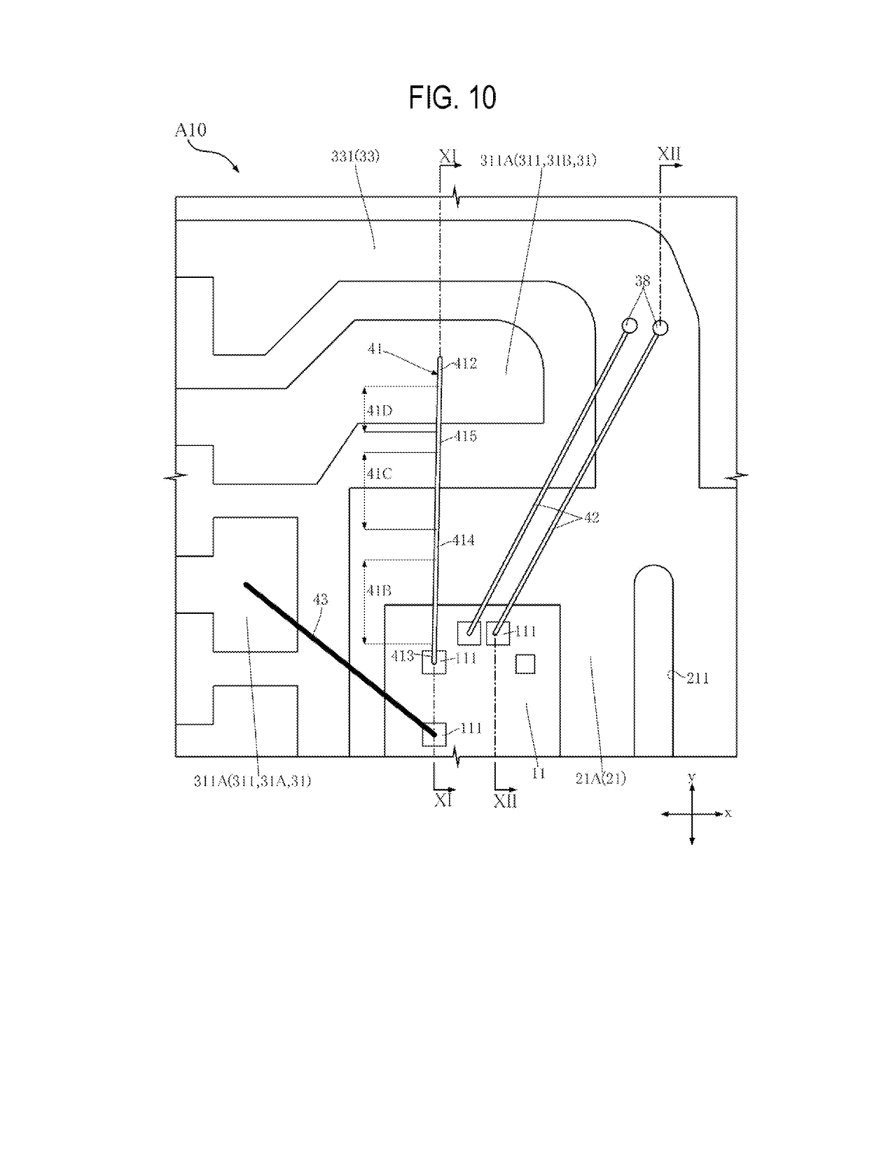

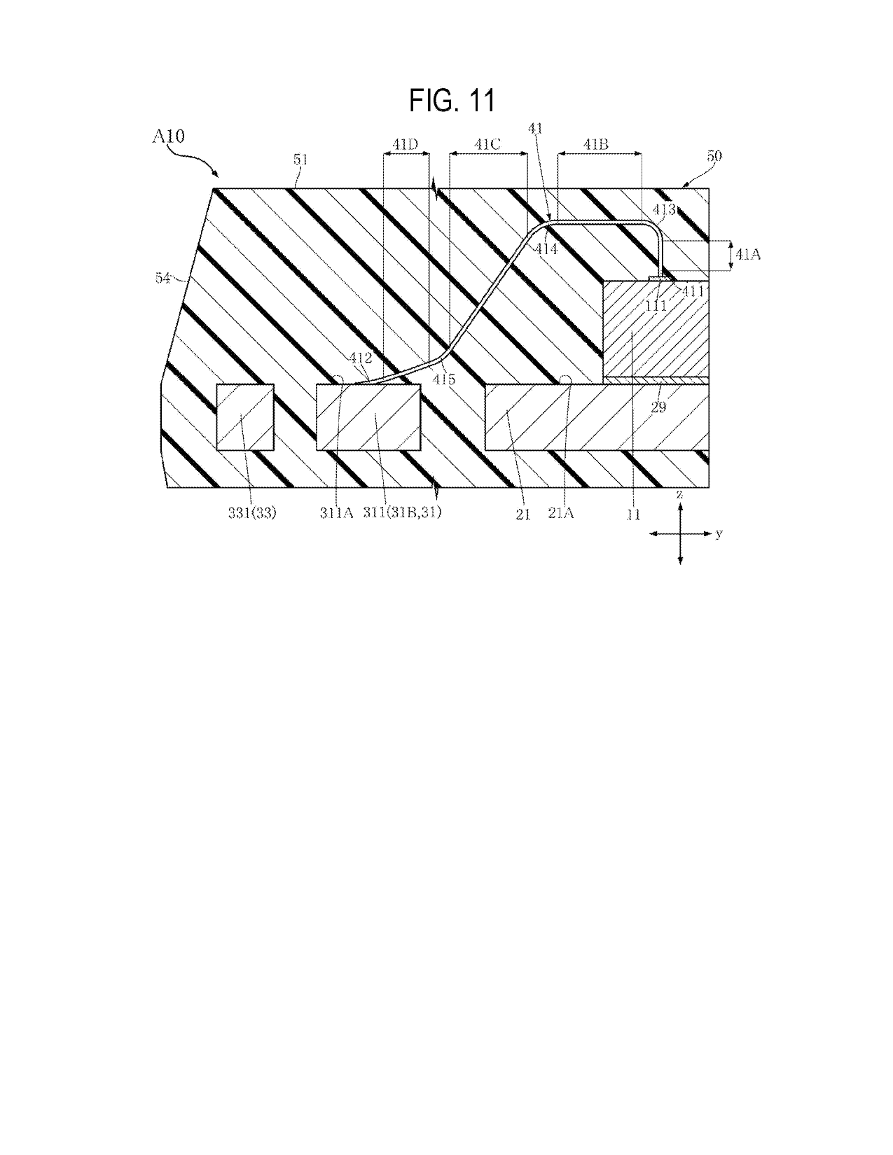

As shown in FIGS. 10 and 11, each of the plurality of first wires 41 includes a first connection portion 411, a second connection portion 412, a first bent portion 413, a second bent portion 414, and a third bent portion 415. The first connection portion 411 is conductively joined to one of the plurality of first electrodes 111 of the first semiconductor element 11. The second connection portion 412 is conductively joined to the first connection surface 311A of one of the two first side leads 31B. The first bent portion 413 is located between the first connection portion 411 and the second connection portion 412. The first bent portion 413 is located closer to the first connection portion 411 than the second connection portion 412. The second bent portion 414 is located between the first bent portion 413 and the second connection portion 412. The third bent portion 415 is located between the second bent portion 414 and the second connection portion 412.

As shown in FIG. 11, each of the first bent portion 413 and the second bent portion 414 has a convex shape facing toward the side moving away from the first mounting surface 21A of the first die pad 21. The third bent portion 415 has a convex shape facing toward the side approaching the first mounting surface 21A. The second bent portion 414 is located on a side of the first semiconductor element 11 opposite the first mounting surface 21A in the first direction z. When viewed in a direction perpendicular to the first direction z, the third bent portion 415 overlaps with the first semiconductor element 11.

As shown in FIG. 10, when viewed in the first direction z, the first bent portion 413 overlaps with the first semiconductor element 11. When viewed in the first direction z, the second bent portion 414 overlaps with the first mounting surface 21A of the first die pad 21. When viewed in the first direction z, the third bent portion 415 is spaced apart from the first mounting surface 21A and the first connection surfaces 311A of the two first side leads 31B.

As shown in FIGS. 10 and 11, each of the plurality of first wires 41 has a first section 41A, a second section 41B, a third section 41C, and a fourth section 41D. The first section 41A connects the first connection portion 411 and the first bent portion 413. The second section 41B connects the first bent portion 413 and the second bent portion 414. When viewed in the first direction z, the second section 41B overlaps with the first mounting surface 21A of the first die pad 21. The third section 41C connects the second bent portion 414 and the third bent portion 415. The fourth section 41D connects the third bent portion 415 and the second connection portion 412. A length of the fourth section 41D is shorter than that of the third section 41C. An inclination angle of the second section 41B with respect to the first mounting surface 21A is smaller than that of the fourth section 41D with respect to the first mounting surface 21A.

As shown in FIG. 2, each of the plurality of second wires 42 is conductively joined to one of the plurality of first electrodes 111 of the first semiconductor element 11 and one of the two first suspension leads 33.

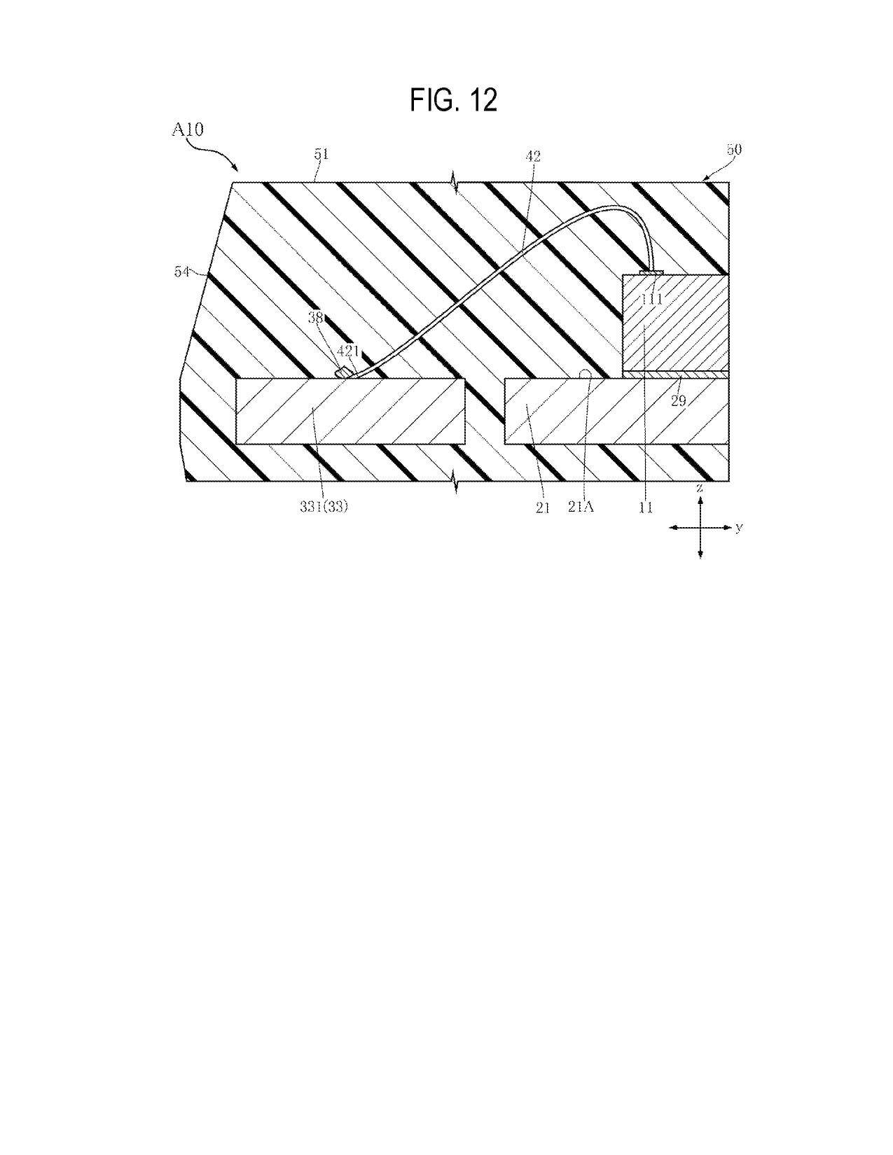

As shown in FIG. 12, each of the plurality of second wires 42 includes a third connection portion 421. The third connection portion 421 is conductively joined to one of the two first suspension leads 33. As shown in FIGS. 11 and 12, a shape of each of the plurality of second wires 42 is different from that of each of the plurality of first wires 41.

As shown in FIGS. 2 and 10, the plurality of first bumps 38 are individually joined to one end of each of the plurality of second wires 42. The plurality of first bumps 38 are conductors containing a metal. As shown in FIG. 12, the third connection portion 421 of each of the plurality of second wires 42 is sandwiched between one of the two first suspension leads 33 and one of the plurality of first bumps 38.

As shown in FIGS. 2 and 7, each of the plurality of third wires 43 is conductively joined to one of the plurality of first electrodes 111 of the first semiconductor element 11 and the first connection surface 311A of one of the plurality of first intermediate leads 31A. As shown in FIGS. 7 and 8, a shape of each of the plurality of third wires 43 is different from that of each of the plurality of first wires 41. Alternatively, the shape of each of the plurality of third wires 43 may be the same as that of each of the plurality of first wires 41.

As shown in FIGS. 1 and 2, the plurality of second leads 32 are located closer to the second die pad 22 than to the first die pad 21 in the second direction x. The second leads 32 are arranged along the third direction y. At least one of the second leads 32 is electrically connected to the second semiconductor element 12.

As shown in FIGS. 2 and 7, each of the plurality of second leads 32 includes a second inner portion 321 and a second outer portion 322. The second inner portion 321 is covered with the sealing resin 50. As shown in FIG. 7, the second inner portion 321 has a second connection surface 321A. The second connection surface 321A faces the same side as the second mounting surface 22A of the second die pad 22 in the first direction z. The second connection surface 321A and the second mounting surface 22A are included in the same plane. The second outer portion 322 is connected to the second inner portion 321. The second outer portion 322 protrudes from the third intermediate portion 553 of the third side surface 55 of the sealing resin 50. When viewed in the first direction z, the second outer portion 322 extends in the second direction x. As shown in FIGS. 3 and 4, the second outer portion 322 is bent in a gull-wing shape when viewed in the third direction y. A surface of the second outer portion 322 is plated with, for example, tin.

As shown in FIG. 2, the plurality of second leads 32 include a plurality of second intermediate leads 32A and two second side leads 32B. The plurality of second intermediate leads 32A are located on a side of the second die pad 22 opposite the first die pad 21 in the second direction x. The two second side leads 32B are located on either side of the second intermediate leads 32A in the third direction y. Each of the two second side leads 32B includes a portion located on either side of the second die pad 22 in the third direction y. A dimension in the second direction x of the second inner portion 321 of each of the two second side leads 32B is larger than that in the second direction x of the second inner portion 321 of each of the second intermediate leads 32A.

As shown in FIGS. 1 and 2, the two second suspension leads 34 are individually connected to both sides of the second die pad 22 in the third direction y. Each of the two second suspension leads 34 is located between one of the two second side leads 32B and one of the plurality of second intermediate leads 32A in the third direction y. Each of the two second suspension leads 34 is spaced apart from the two second side surfaces 54 of the sealing resin 50. Each of the two second suspension leads 34 includes a fourth inner portion 341 and a fourth outer portion 342. The fourth inner portion 341 is connected to the second die pad 22 and is covered with the sealing resin 50. The fourth outer portion 342 is connected to the fourth inner portion 341. The fourth outer portion 342 protrudes from the third intermediate portion 553 of the third side surface 55 of the sealing resin 50. When viewed in the first direction z, the fourth outer portion 342 extends in the second direction x. The fourth outer portion 342 is bent in a gull-wing shape when viewed in the third direction y. A shape of the fourth outer portion 342 is the same as that of the second outer portion 322 of each of the two second side leads 32B (see FIGS. 3 and 4). A surface of the fourth outer portion 342 is plated with, for example, tin.

As shown in FIGS. 2 and 9, each of the plurality of fourth wires 44 is conductively joined to one of the plurality of second electrodes 121 of the second semiconductor element 12 and the second connection surface 321A of one of the two second side leads 32B.

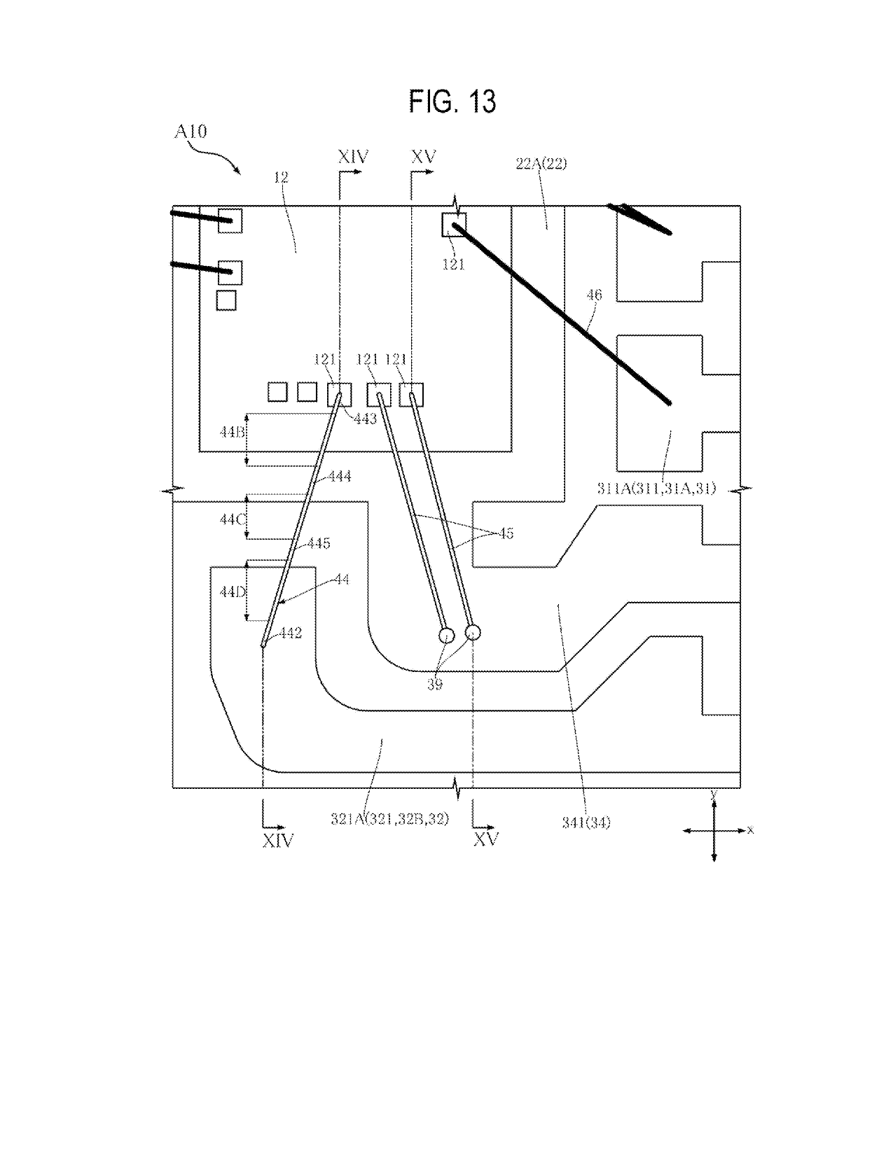

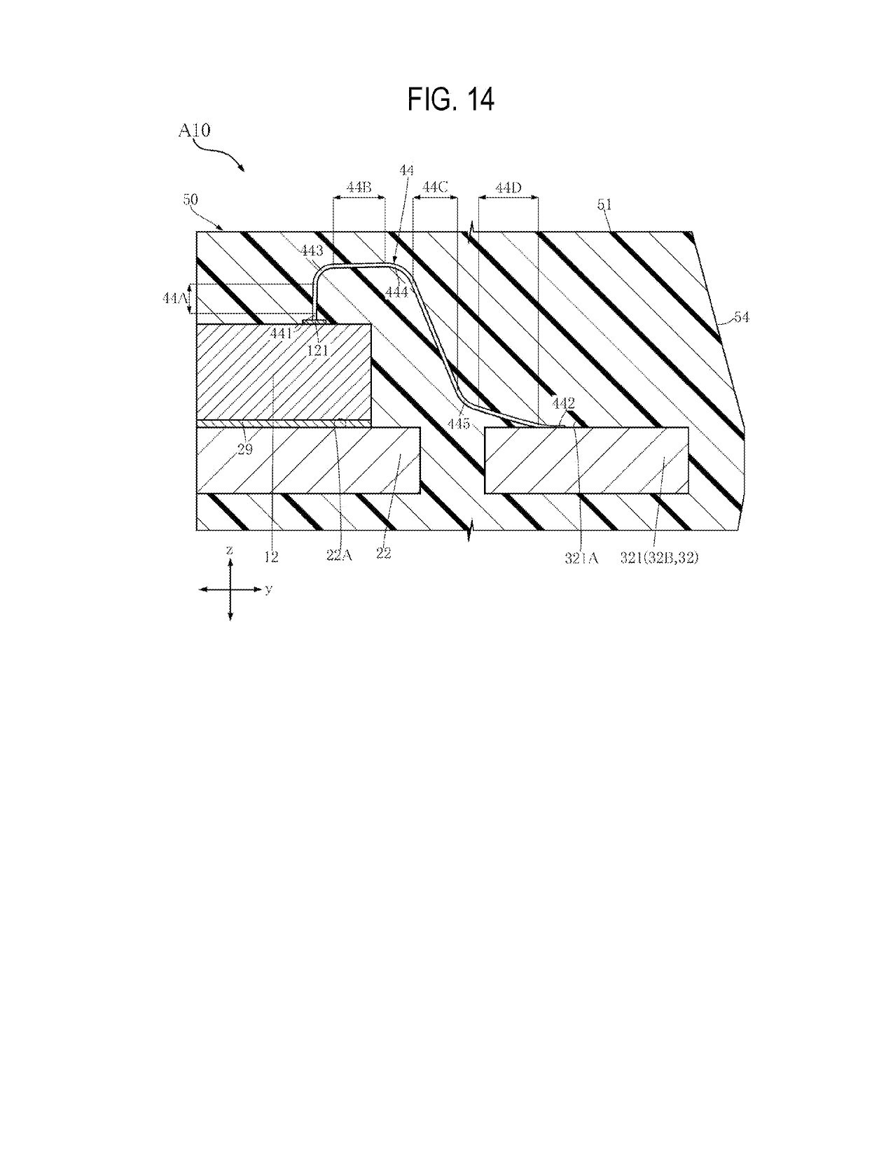

As shown in FIGS. 13 and 14, each of the plurality of fourth wires 44 includes a first connection portion 441, a second connection portion 442, a first bent portion 443, a second bent portion 444, and a third bent portion 445. The first connection portion 441 is conductively joined to one of the plurality of second electrodes 121 of the second semiconductor element 12. The second connection portion 442 is conductively joined to the second connection surface 321A of one of the two second side leads 32B. The first bent portion 443 is located between the first connection portion 441 and the second connection portion 442. The first bent portion 443 is located closer to the first connection portion 441 than to the second connection portion 442. The second bent portion 444 is located between the first bent portion 443 and the second connection portion 442. The third bent portion 445 is located between the second bent portion 444 and the second connection portion 442.

As shown in FIG. 14, each of the first bent portion 443 and the second bent portion 444 has a convex shape facing toward the side moving away from the second mounting surface 22A of the second die pad 22. The third bent portion 445 has a convex shape facing toward the side approaching the second mounting surface 22A. The second bent portion 444 is located on a side of the second semiconductor element 12 opposite the second mounting surface 22A in the first direction z. When viewed in a direction perpendicular to the first direction z, the third bent portion 445 overlaps with the second semiconductor element 12.

As shown in FIG. 13, when viewed in the first direction z, the first bent portion 443 overlaps with the second semiconductor element 12. When viewed in the first direction z, the second bent portion 444 overlaps with the second mounting surface 22A of the second die pad 22. When viewed in the first direction z, the third bent portion 445 is spaced apart from the second mounting surface 22A and the second connection surfaces 321A of the two second side leads 32B.

As shown in FIGS. 13 and 14, each of the plurality of fourth wires 44 has a first section 44A, a second section 44B, a third section 44C, and a fourth section 44D. The first section 44A connects the first connection portion 441 and the first bent portion 443. The second section 44B connects the first bent portion 443 and the second bent portion 444. When viewed in the first direction z, the second section 44B overlaps with the second mounting surface 22A of the second die pad 22. The third section 44C connects the second bent portion 444 and the third bent portion 445. The fourth section 44D connects the third bent portion 445 and the second connection portion 442. A length of the fourth section 44D is shorter than that of the third section 44C. An inclination angle of the second section 44B with respect to the second mounting surface 22A is smaller than that of the fourth section 44D with respect to the second mounting surface 22A.

As shown in FIG. 2, each of the plurality of fifth wires 45 is conductively joined to one of the plurality of second electrodes 121 of the second semiconductor element 12 and one of the two second suspension leads 34.

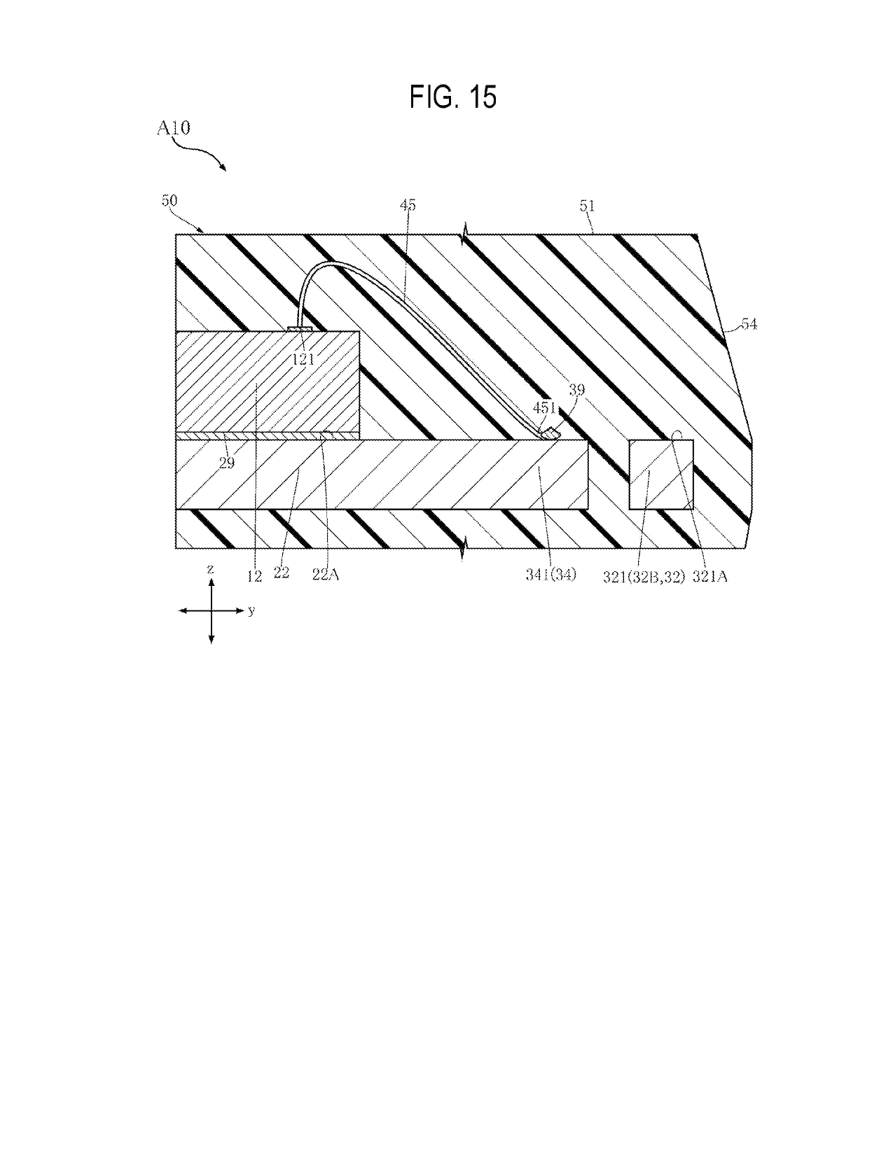

As shown in FIG. 15, each of the plurality of fifth wires 45 includes a fourth connection portion 451. The fourth connection portion 451 is conductively joined to one of the two second suspension leads 34. As shown in FIGS. 14 and 15, a shape of each of the plurality of fifth wires 45 is different from that of each of the plurality of fourth wires 44.

As shown in FIGS. 2 and 13, the plurality of second bumps 39 are individually joined to one end of each of the fifth wires 45. The second bumps 39 are conductors containing a metal. As shown in FIG. 15, the fourth connection portion 451 of each of the fifth wires 45 is sandwiched between one of the two second suspension leads 34 and one of the second bumps 39.

As shown in FIGS. 2 and 7, each of the plurality of sixth wires 46 is conductively joined to one of the plurality of second electrodes 121 of the second semiconductor element 12 and the second connection surface 321A of one of the plurality of second intermediate leads 32A. As shown in FIGS. 7 and 9, a shape of each of the plurality of sixth wires 46 is different from that of each of the plurality of fourth wires 44. Alternatively, the shape of each of the plurality of sixth wires 46 may be the same as the shape of each of the plurality of fourth wires 44.

As shown in FIGS. 2 and 7, each of the plurality of seventh wires 47 is conductively joined to one of the plurality of third electrodes 131 of the insulating element 13 and one of the plurality of first electrodes 111 of the first semiconductor element 11. Thus, the first semiconductor element 11 is electrically connected to the insulating element 13. The plurality of seventh wires 47 are arranged along the third direction y. When viewed in the first direction z, one of the plurality of sixth wires 46 intersects with one of the plurality of first through-holes 211 provided in the first die pad 21.

As shown in FIGS. 2 and 7, each of the plurality of eighth wires 48 is conductively joined to one of the plurality of fourth electrodes 132 of the insulating element 13 and one of the plurality of second electrodes 121 of the second semiconductor element 12. Thus, the second semiconductor element 12 is electrically connected to the insulating element 13. The plurality of eighth wires 48 are arranged along the third direction y. When viewed in the first direction z, each of the plurality of eighth wires 48 intersects with a gap between the first die pad 21 and the second die pad 22.

As shown in FIGS. 3 and 4, a gate mark 56 is formed on each of the two second side surfaces 54 of the sealing resin 50. The gate mark 56 on each of the two second side surfaces 54 is formed as the sealing resin 50 is separated from a resin filled in a runner of the molding die when the sealing resin 50 is formed by transfer molding. Therefore, a surface roughness of the gate mark 56 on each of the two second side surfaces 54 is greater than those of other regions of each of the two second side surfaces 54.

As shown in FIGS. 3 and 4, the gate marks 56 on the two second side surfaces 54 are spaced apart from each other in the second direction x. When viewed in the third direction y, one of the gate marks 56 on the two second side surfaces 54 overlaps with the third inner portion 331 of one of the two first suspension leads 33.

In general, a motor driver circuit in an inverter device is provided with a half-bridge circuit including a low-side (low-potential-side) switching element and a high-side (high-potential-side) switching element. The following description focuses on a case where these switching elements are MOSFETs. In the low-side switching element, reference potentials of a source of the switching element and a gate driver for driving the switching element are both grounded. On the other hand, in the high-side switching element, reference potentials of a source of the switching element and a gate driver for driving the switching element both correspond to a potential at an output node of the half-bridge circuit. The potential at the output node is changed according to the driving of the high-side switching element and the low-side switching element. Therefore, the reference potential of the gate driver for driving the high-side switching element is also changed. When the high-side switching element is turned on, the reference potential is equivalent to a voltage applied to a drain of the high-side switching element (for example, 600 V or higher). In the semiconductor device A10, the ground of the first semiconductor element 11 and the ground of the second semiconductor element 12 are configured to be separated from each other. Therefore, when the semiconductor device A10 is used as the gate driver for driving the high-side switching element, a voltage equivalent to the voltage applied to the drain of the high-side switching element is transiently applied to the ground of the second semiconductor element 12.

Next, effects of the semiconductor device A10 will be described.

The semiconductor device A10 includes the first die pad 21, the first semiconductor element 11, the plurality of first leads 31, and the first wire 41. The first wire 41 includes the first connection portion 411, the second connection portion 412, the first bent portion 413, the second bent portion 414, and the third bent portion 415. Each of the first bent portion 413 and the second bent portion 414 has a convex shape facing toward the side moving away from the first mounting surface 21A of the first die pad 21. The third bent portion 415 has a convex shape facing toward the side approaching the first mounting surface 21A. By adopting this configuration, during the manufacture of the semiconductor device A10, the first wire 41 conductively joined to the first connection surface 311A of one of the plurality of first leads 31 is more likely to be elastically deformed in response to the displacement of the first lead 31 in the first direction z. As a result, a component of a tensile force acting on the second connection portion 412 in the first direction z is further reduced according to the displacement of the first lead 31 in the first direction z. Therefore, according to this configuration of the semiconductor device A10, during the manufacture of the semiconductor device A10, it is possible to more effectively prevent the first wire 41 conductively joined to one of the plurality of first leads 31 from being broken.

The first wire 41 includes the first section 41A, the second section 41B, the third section 41C, and the fourth section 41D. The inclination angle of the second section 41B with respect to the first mounting surface 21A of the first die pad 21 is smaller than the inclination angle of the fourth section 41D with respect to the first mounting surface 21A. This configuration makes the first wire 41 more susceptible to elastic deformation in response to the displacement of the first lead 31 in the first direction z. Therefore, the component of the tensile force acting on the second connection portion 412 in the first direction z is further reduced according to the displacement of the first lead 31 in the first direction z.

The plurality of first leads 31 include the first intermediate lead 31A and the first side lead 31B. The first side lead 31B is located on one side of the first intermediate lead 31A in the third direction y and includes the portion located on one side of the first die pad 21 in the third direction y. With this configuration, the dimension in the second direction x of the first inner portion 311 of the first side lead 31B is larger than the dimension in the second direction x of the first inner portion 311 of the first intermediate lead 31A. Therefore, the first side lead 31B is more likely to bend in the first direction z than the first intermediate lead 31A. Accordingly, by conductively joining the second connection portion 412 of the first wire 41 to the first connection surface 311A of the first side lead 31B, the configuration of the semiconductor device A10 becomes more desirable.

The semiconductor device A10 further includes the two first suspension leads 33 and the fourth wire 44. The fourth wire 44 is conductively joined to one of the two first suspension leads 33. During the manufacture of the semiconductor device A10, the displacement of each of the two first suspension leads 33 in the first direction z follows the displacement of the first die pad 21 in the first direction z. Therefore, the displacement of each of the two first suspension leads 33 in the first direction z is smaller than that of each of the plurality of first leads 31 in the first direction z. Accordingly, the shape of the second wire 42 may be made different from that of the first wire 41 and may be the same as a shape of a wire in the related art.

The semiconductor device A10 further includes the first bump 38. The third connection portion 421 of the second wire 42 is sandwiched between one of the two first suspension leads 33 and the first bump 38. With this configuration, the third connection portion 421 and one of the two first suspension leads 33 are more firmly joined to each other.

The semiconductor device A10 further includes the sealing resin 50. The gate mark 56 is formed on each of the two second side surfaces 54 of the sealing resin 50. When viewed in the third direction y, the gate mark 56 formed on either of the two second side surfaces 54 overlaps with the first side lead 31B. By adopting this configuration, when the sealing resin 50 is formed in the manufacturing process of the semiconductor device A10, the first wire 41 conductively joined to the first side lead 31B is more likely to resist a flow of the sealing resin 50 in a molten state.

The first die pad 21 is provided with the plurality of first through-holes 211, each of which penetrates in the first direction z. The plurality of first through-holes 211 are located between the first semiconductor element 11 and the insulating element 13 in the second direction x. With this configuration, when the sealing resin 50 is formed in the manufacturing process of the semiconductor device A10, the sealing resin 50 in a molten state passes through the plurality of first through-holes 211, thereby making the sealing resin 50 more densely filled.

### Second Embodiment

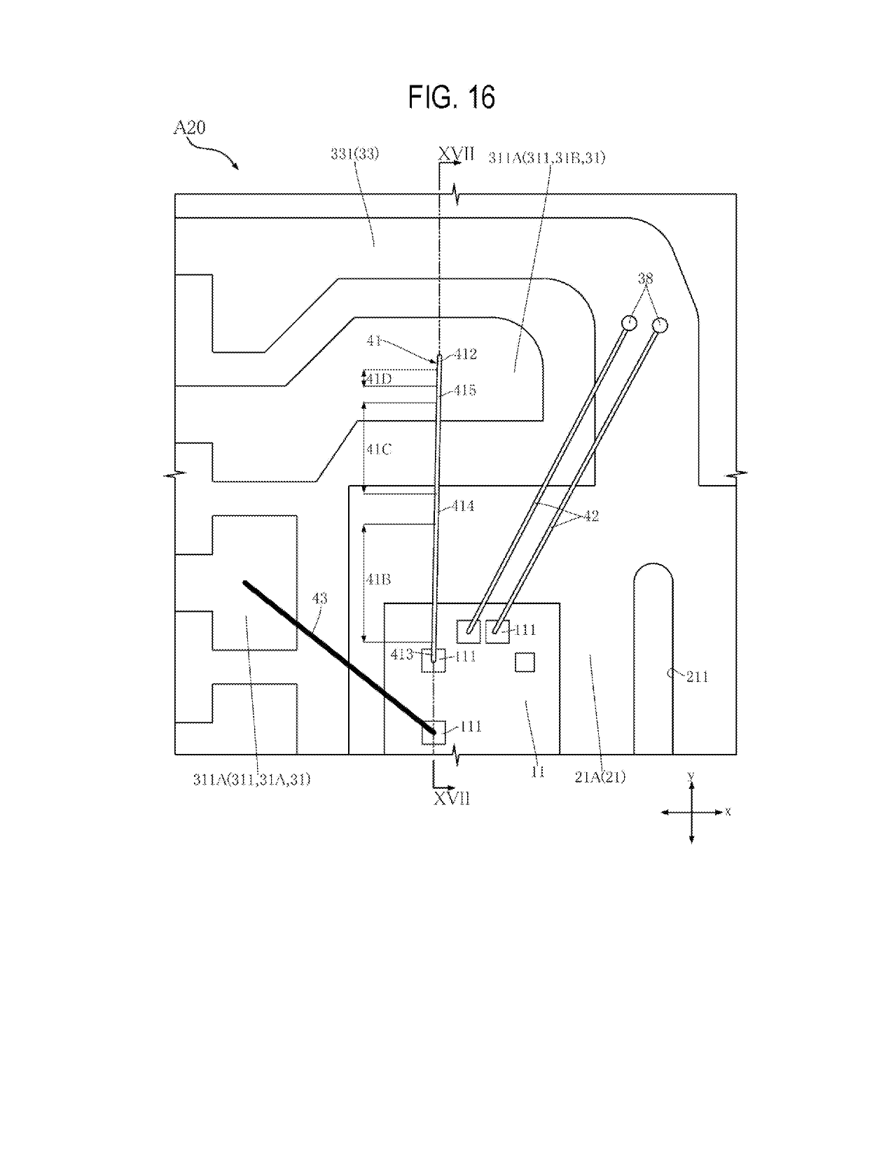

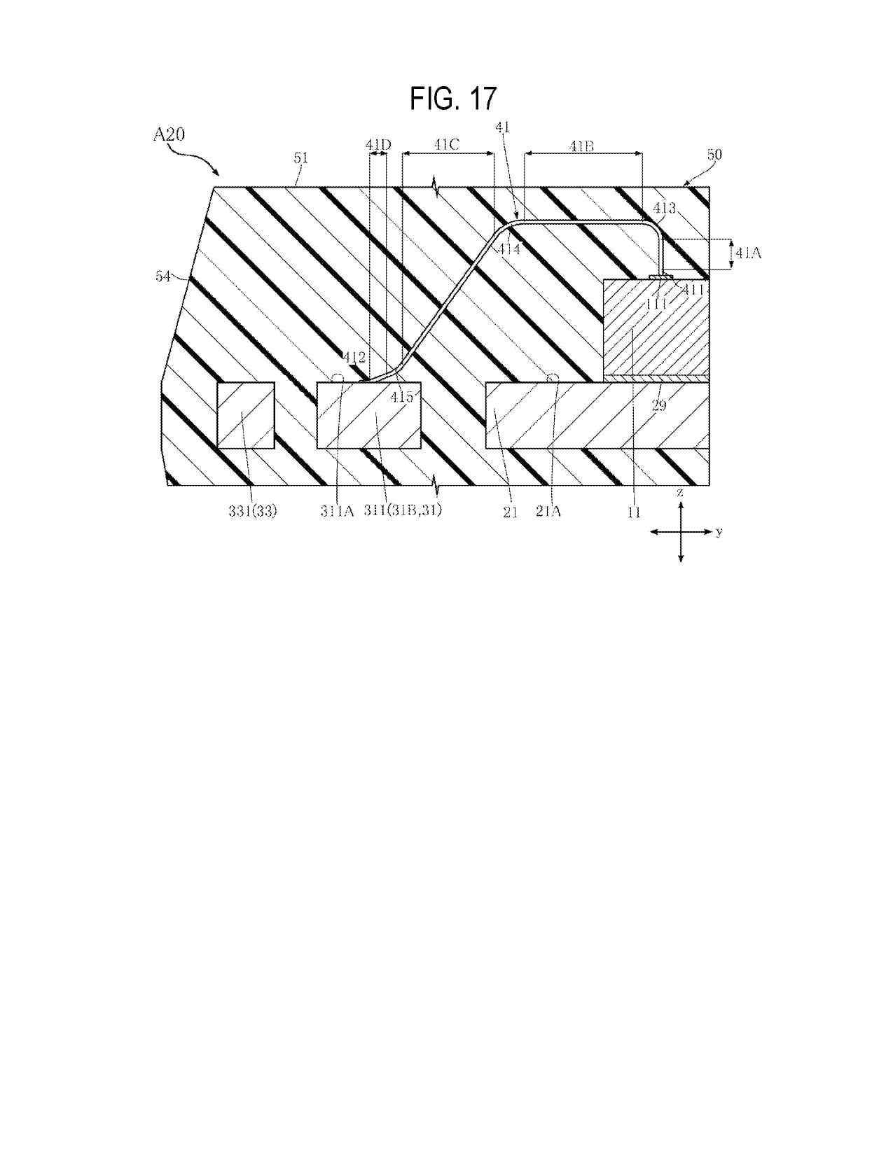

A semiconductor device A20 according to a second embodiment of the present disclosure will be described with reference to FIGS. 16 and 17. In these figures, elements that are identical or similar to those of the semiconductor device A10 described above are designated by the same reference numerals, and redundant descriptions thereof will be omitted. In this regard, FIG. 16 corresponds to FIG. 10 which shows the semiconductor device A10.

In the semiconductor device A20, a configuration of the plurality of first wires 41 is different from that of the semiconductor device A10.

As shown in FIGS. 16 and 17, when viewed in the first direction z, the third bent portion 415 and the third section 41C of each of the plurality of first wires 41 overlap with the second connection surface 321A of one of the two first suspension leads 33.

Next, effects of the semiconductor device A20 will be described.

The semiconductor device A20 includes the first die pad 21, the first semiconductor element 11, the plurality of first leads 31, and the first wire 41. The first wire 41 includes the first connection portion 411, the second connection portion 412, the first bent portion 413, the second bent portion 414, and the third bent portion 415. The first bent portion 413 and the second bent portion 414 have a convex shape facing toward the side moving away from the first mounting surface 21A of the first die pad 21. The third bent portion 415 has a convex shape facing toward the side approaching the first mounting surface 21A. Therefore, according to this configuration, even in the semiconductor device A20, the first wire 41 conductively joined to one of the plurality of first leads 31 may be more effectively suppressed from being broken during the manufacture of the semiconductor device A20. Further, by sharing the configuration common to the semiconductor device A10, the semiconductor device A20 achieves the same effects as those of the semiconductor device A10.

### Third Embodiment

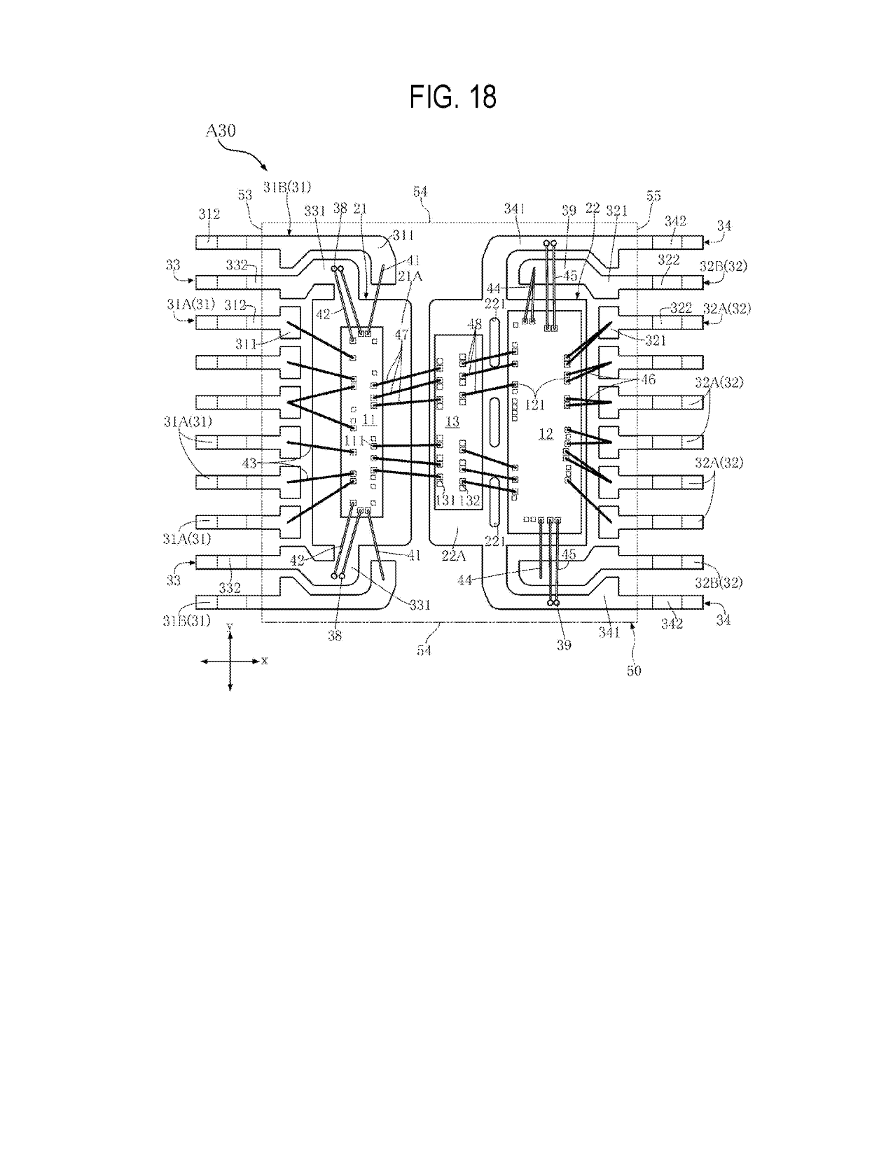

A semiconductor device A30 according to a third embodiment of the present disclosure will be described with reference to FIG. 18. In this figure, elements identical or similar to those of the aforementioned semiconductor device A10 are designated by the same reference numerals, and redundant descriptions thereof will be omitted. For ease of understanding, FIG. 18 shows the sealing resin 50 as being transparent. In FIG. 18, the outline of the sealing resin 50 is shown by imaginary lines.

In the semiconductor device A30, configurations of the insulating element 13, the first die pad 21, and the second die pad 22 are different from those of the semiconductor device A10.

As shown in FIG. 18, the insulating element 13 is mounted on the second mounting surface 22A of the second die pad 22. In this case, an area of the second die pad 22 is larger than that of the first die pad 21 when viewed in the first direction z.

As shown in FIG. 18, the first die pad 21 does not have the plurality of first through-holes 211. The second die pad 22 has a plurality of second through-holes 221. Each of the plurality of second through-holes 221 penetrates the second die pad 22 in the first direction z and extends in the third direction y. The plurality of second through-holes 221 are arranged along the third direction y. The plurality of second through-holes 221 are located between the second semiconductor element 12 and the insulating element 13 in the second direction x. When viewed in the first direction z, one of the plurality of eighth wires 48 intersects with one of the plurality of second through-holes 221.

Next, effects of the semiconductor device A30 will be described.

The semiconductor device A30 includes the first die pad 21, the first semiconductor element 11, the plurality of first leads 31, and the first wire 41. The first wire 41 includes the first connection portion 411, the second connection portion 412, the first bent portion 413, the second bent portion 414, and the third bent portion 415. The first bent portion 413 and the second bent portion 414 have a convex shape facing toward the side moving away from the first mounting surface 21A of the first die pad 21. The third bent portion 415 has a convex shape facing toward the side approaching the first mounting surface 21A. Therefore, according to this configuration, even in the semiconductor device A30, the first wire 41 conductively joined to one of the plurality of first leads 31 may be more effectively suppressed from being broken during the manufacture of the semiconductor device A30. Further, by sharing the configuration common to the semiconductor device A10, the semiconductor device A30 achieves the same effects as those of the semiconductor device A10.

### Fourth Embodiment

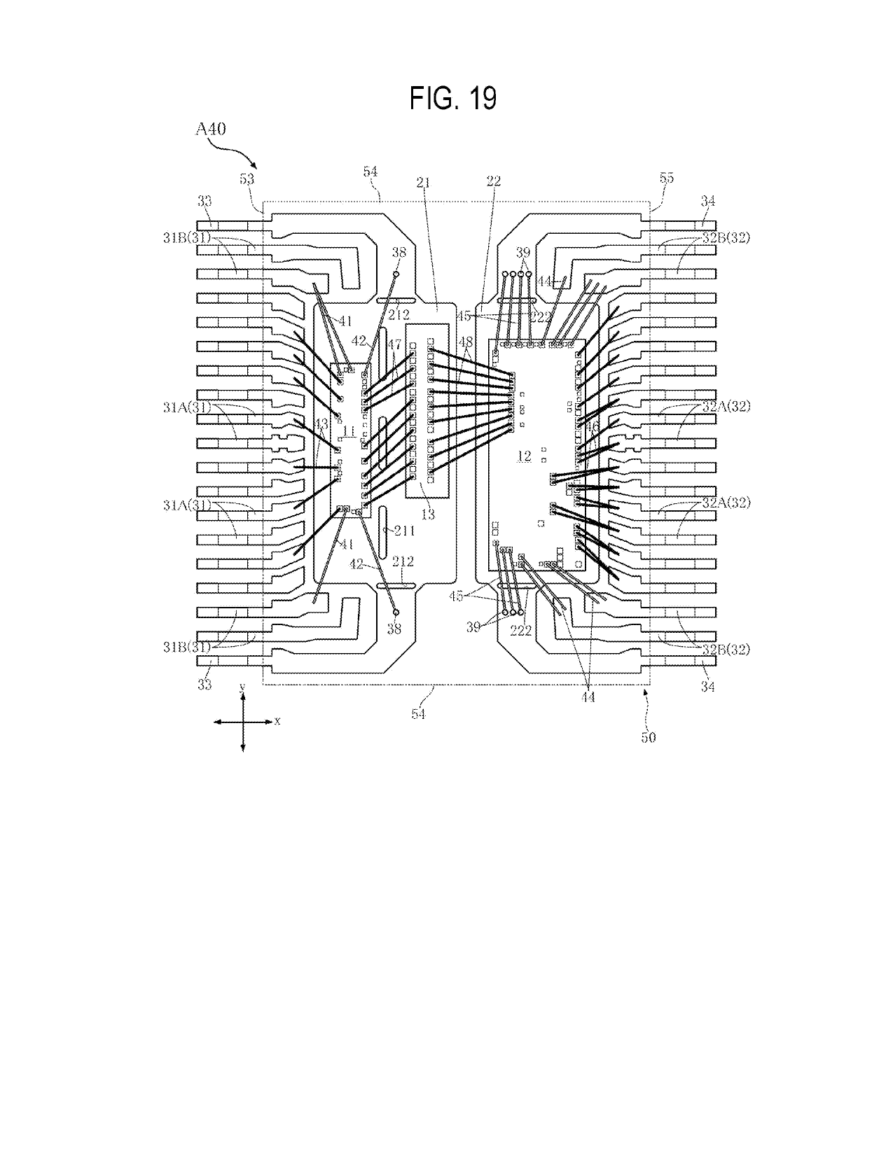

A semiconductor device A40 according to a fourth embodiment of the present disclosure will be described with reference to FIG. 19. In this figure, elements identical or similar to those of the previously described semiconductor device A10 are designated by the same reference numerals, and redundant descriptions thereof will be omitted. For ease of understanding, FIG. 19 shows the sealing resin 50 as being transparent. In FIG. 19, the outline of the sealing resin 50 is shown by imaginary lines.

The semiconductor device A40 differs from the semiconductor device A10 in that it includes four first side leads 31B and four second side leads 32B instead of the two first side leads 31B and the two second side leads 32B, and in terms of the configurations of the first die pad 21 and the second die pad 22.

As shown in FIG. 19, among the four first side leads 31B, two first side leads 31B are located between the plurality of first intermediate leads 31A and either of the two first suspension leads 33 in the third direction y. Among the four first side leads 31B, the remaining two first side leads 31B are located on a side opposite the two first side leads 31B in the third direction y with the plurality of first intermediate leads 31A sandwiched therebetween.

As shown in FIG. 19, among the four second side leads 32B, two second side leads 32B are located between the plurality of second intermediate leads 32A and either of the two second suspension leads 34 in the third direction y. Among the four second side leads 32B, the remaining two second side leads 32B are located on a side opposite the two second side leads 32B in the third direction y with the plurality of second intermediate leads 32A sandwiched therebetween.

As shown in FIG. 19, the first die pad 21 has two first openings 212. Each of the two first openings 212 penetrates the first die pad 21 in the first direction z and extends in the second direction x. Each of the two first openings 212 is located at a boundary between the first die pad 21 and one of the two first suspension leads 33.

As shown in FIG. 19, the second die pad 22 has two second openings 222. Each of the two second openings 222 penetrates the second die pad 22 in the first direction z and extends in the second direction x. Each of the two second openings 222 is located at a boundary between the second die pad 22 and one of the two second suspension leads 34.

Next, effects of the semiconductor device A40 will be described.

The semiconductor device A40 includes the first die pad 21, the first semiconductor element 11, the plurality of first leads 31, and the first wire 41. The first wire 41 includes the first connection portion 411, the second connection portion 412, the first bent portion 413, the second bent portion 414, and the third bent portion 415. The first bent portion 413 and the second bent portion 414 have a convex shape facing toward the side moving away from the first mounting surface 21A of the first die pad 21. The third bent portion 415 has a convex shape facing toward the side approaching the first mounting surface 21A. Therefore, according to this configuration, even in the semiconductor device A40, the first wire 41 conductively joined to one of the plurality of first leads 31 may be more effectively suppressed from being broken during the manufacture of the semiconductor device A40. Further, by sharing the configuration common to the semiconductor device A10, the semiconductor device A40 achieves the same effects as those of the semiconductor device A10.

The present disclosure is not limited to the above-described embodiments, and a specific configuration of each part of the present disclosure may be modified in design in various ways.

The present disclosure includes embodiments set forth in the following supplementary notes.

### Supplementary Note 1

A semiconductor device A10, comprising:

a first die pad 21 having a first mounting surface 21A facing one side in a first direction z;

a first semiconductor element 11 including a first electrode 111 located on an opposite side of the one side to which the first mounting surface faces in the first direction, the first semiconductor element 11 being mounted on the first mounting surface;

a plurality of first leads 31 each having a first connection surface 311A facing the one side to which the first mounting surface faces in the first direction, the plurality of first leads being spaced apart from the first die pad; and

a first wire 41 conductively joined to the first electrode and the first connection surface of one of the plurality of first leads,

wherein the first wire includes a first connection portion 411 conductively joined to the first electrode, a second connection portion 412 conductively joined to the first connection surface, a first bent portion 413 located between the first connection portion and the second connection portion, a second bent portion 414 located between the first bent portion and the second connection portion, and a third bent portion 415 located between the second bent portion and the second connection portion,

wherein each of the first bent portion and the second bent portion has a convex shape facing toward the side moving away from the first mounting surface, and

wherein the third bent portion has a convex shape facing toward the side approaching the first mounting surface.

### Supplementary Note 2

In the semiconductor device A10 of Supplementary Note 1 above, the second bent portion 414 is located on a side of the first semiconductor element 11 opposite the first mounting surface 21A in the first direction z.

### Supplementary Note 3

In the semiconductor device A10 of Supplementary Note 2 above, when viewed in the first direction z, the first bent portion 413 overlaps with the first semiconductor element 11.

### Supplementary Note 4

In the semiconductor device A10 of Supplementary Note 3 above, when viewed in a direction perpendicular to the first direction z, the third bent portion 415 overlaps with the first semiconductor element 11.

### Supplementary Note 5

In the semiconductor device A10 of Supplementary Note 4 above, the first wire 41 includes a first section 41A connecting the first connection portion 411 and the first bent portion 413, and a second section 41B connecting the first bent portion and the second bent portion 414, and

the second section overlaps with the first mounting surface 21A when viewed in the first direction z.

### Supplementary Note 6

In the semiconductor device A10 of Supplementary Note 5 above, when viewed in the first direction z, the third bent portion 415 is spaced apart from the first mounting surface 21A.

### SUPPLEMENTARY NOTE 7

In the semiconductor device A10 of Supplementary Note 6 above, when viewed in the first direction z, the second bent portion 414 overlaps with the first mounting surface 21A.

### Supplementary Note 8

In the semiconductor device A20 of Supplementary Note 6 above, when viewed in the first direction z, the third bent portion 415 overlaps with the first connection surface 311A.

### Supplementary Note 9

In the semiconductor device A10 of Supplementary Note 7 above, the first wire 41 includes a third section 41C connecting the second bent portion 414 and the third bent portion 415, and a fourth section 41D connecting the third bent portion and the second connection portion 412, and

an inclination angle of the second section 41B with respect to the first mounting surface 21A is smaller than an inclination angle of the fourth section with respect to the first mounting surface.

### Supplementary Note 10

In the semiconductor device A10 of any one of Supplementary Notes 5 to 9 above, the plurality of first leads 31 include a first intermediate lead 31A and a first side lead 31B,

the first intermediate lead is located on one side of the first die pad 21 in a second direction x perpendicular to the first direction z,

the first side lead is located on one side of the first intermediate lead in a third direction y perpendicular to both the first direction and the second direction,

the first side lead includes a portion located on one side of the first die pad in the third direction, and

the second connection portion 412 is conductively joined to the first connection surface 311A of the first side lead.

### Supplementary Note 11

The semiconductor device A10 of Supplementary Note 10 above further includes:

two first suspension leads 33 individually connected to both sides of the first die pad 21 in the third direction y,

wherein the first intermediate lead 31A is located between the two first suspension leads in the third direction, and

the first side lead 31B is located to be adjacent to either of the two first suspension leads in the third direction.

### Supplementary Note 12

The semiconductor device A10 of Supplementary Note 11 above further includes:

a second wire 42,

wherein the first semiconductor element 11 includes an additional first electrode 111 located on the opposite side in the first direction z,

wherein the second wire is conductively joined to the additional first electrode and one of the two first suspension leads 33, and

wherein a shape of the second wire is different from a shape of the first wire 41.

### Supplementary Note 13

The semiconductor device A10 of Supplementary Note 12 above further includes:

a first bump 38 which is a conductor,

wherein the second wire 42 includes a third connection portion 421 conductively joined to one of the two first suspension leads 33, and

wherein the third connection portion is sandwiched between one of the two first suspension leads and the first bump.

### Supplementary Note 14

The semiconductor device A10 of Supplementary Note 12 above further includes:

a sealing resin 50 configured to cover the first die pad 21, the first semiconductor element 11, the first wire 41, and the second wire 42,

wherein the sealing resin has a first side surface 53 facing a side on which the first intermediate lead 31A is located with reference to the first die pad in the second direction x, and

wherein each of the plurality of first leads 31 and the two first suspension leads 33 protrudes from the first side surface.

### Supplementary Note 15

In the semiconductor device A10 of Supplementary Note 14 above, the sealing resin 50 has two second side surfaces 54 facing in different sides in the third direction y, and

each of the two first suspension leads 33 is spaced apart from the two second side surfaces.

### Supplementary Note 16

In the semiconductor device A10 of Supplementary Note 15 above, a gate mark 56 is formed on each of the two second side surfaces 54,

a surface roughness of the gate mark is greater than a surface roughness of other regions of each of the two second side surfaces, and

the gate mark formed on either of the two second side surfaces overlaps with the first side lead 31B when viewed in the third direction y.

### Supplementary Note 17

The semiconductor device A10 of Supplementary Note 15 above further includes:

a second die pad 22 located on a side of the first die pad 21 opposite the first intermediate lead 31A in the second direction x;

a second semiconductor element 12 mounted on the second die pad; and

an insulating element 13 electrically conductive with each of the first semiconductor element 11 and the second semiconductor element,

wherein the insulating element is of an inductively coupled type, and is mounted on the first mounting surface 21A.

### Supplementary Note 18

The semiconductor device A10 of Supplementary Note 17 above further includes:

a plurality of second leads 32, each of which is electrically connected to the second semiconductor element 12,

wherein the sealing resin 50 has a third side surface 55 facing a side opposite the first side surface 53 in the second direction x, and

wherein each of the second leads protrudes from the third side surface.

### Supplementary Note 19

In the semiconductor device A10 of Supplementary Note 18 above, the plurality of second leads 32 include a second intermediate lead 32A and a second side lead 32B,

the second intermediate lead is located on a side of the second die pad 22 opposite the first die pad 21 in the second direction x,

the second side lead is located on one side of the second intermediate lead in the third direction y, and

the second side lead includes a portion located on one side of the second die pad in the third direction.

### Supplementary Note 20

The semiconductor device A10 of Supplementary Note 19 above further includes:

two second suspension leads 34 individually connected to both sides of the second die pad 22 in the third direction y,

wherein the second intermediate lead 32A is located between the two second suspension leads in the third direction, and

wherein the second side lead 32B is located to be adjacent to either of the two second suspension leads in the third direction.

### Supplementary Note 21

In the semiconductor device A10 of Supplementary Note 20 above, each of the two second suspension leads 34 is spaced apart from the two second side surfaces 54.

While certain embodiments have been described, these embodiments have been presented by way of example only, and are not intended to limit the scope of the disclosures. Indeed, the embodiments described herein may be embodied in a variety of other forms. Further, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device, comprising:
a first die pad having a first mounting surface facing one side in a first direction;
a first semiconductor element including a first electrode located on an opposite side of the one side to which the first mounting surface faces in the first direction, the first semiconductor element being mounted on the first mounting surface;
a plurality of first leads each having a first connection surface facing the one side to which the first mounting surface faces in the first direction, the plurality of first leads being spaced apart from the first die pad; and
a first wire conductively joined to the first electrode and the first connection surface of one of the plurality of first leads,
wherein the first wire includes a first connection portion conductively joined to the first electrode, a second connection portion conductively joined to the first connection surface, a first bent portion located between the first connection portion and the second connection portion, a second bent portion located between the first bent portion and the second connection portion, and a third bent portion located between the second bent portion and the second connection portion,
wherein each of the first bent portion and the second bent portion has a convex shape facing toward the side moving away from the first mounting surface, and
wherein the third bent portion has a convex shape facing a side approaching the first mounting surface.

2. The semiconductor device of claim 1, wherein the second bent portion is located on a side of the first semiconductor element opposite the first mounting surface in the first direction.

3. The semiconductor device of claim 2, wherein, when viewed in the first direction, the first bent portion overlaps with the first semiconductor element.

4. The semiconductor device of claim 3, wherein, when viewed in a direction perpendicular to the first direction, the third bent portion overlaps with the first semiconductor element.

5. The semiconductor device of claim 4, wherein the first wire has a first section connecting the first connection portion and the first bent portion, and a second section connecting the first bent portion and the second bent portion, and
wherein the second section overlaps with the first mounting surface when viewed in the first direction.

6. The semiconductor device of claim 5, wherein, when viewed in the first direction, the third bent portion is spaced apart from the first mounting surface.

7. The semiconductor device of claim 6, wherein, when viewed in the first direction, the second bent portion overlaps with the first mounting surface.

8. The semiconductor device of claim 5, wherein, when viewed in the first direction, the third bent portion overlaps with the first connection surface.

9. The semiconductor device of claim 7, wherein the first wire has a third section connecting the second bent portion and the third bent portion, and a fourth section connecting the third bent portion and the second connection portion, and
wherein an inclination angle of the second section with respect to the first mounting surface is smaller than an inclination angle of the fourth section with respect to the first mounting surface.

10. The semiconductor device of claim 5, wherein the plurality of first leads include a first intermediate lead and a first side lead,
wherein the first intermediate lead is located on one side of the first die pad in a second direction perpendicular to the first direction,
wherein the first side lead is located on one side of the first intermediate lead in a third direction perpendicular to both the first direction and the second direction,
wherein the first side lead includes a portion located on one side of the first die pad in the third direction, and
wherein the second connection portion is conductively joined to the first connection surface of the first side lead.

11. The semiconductor device of claim 10, further comprising:
two first suspension leads individually connected to both sides of the first die pad in the third direction,
wherein the first intermediate lead is located between the two first suspension leads in the third direction, and
wherein the first side lead is located to be adjacent to either of the two first suspension leads in the third direction.

12. The semiconductor device of claim 11, further comprising:
a second wire,
wherein the first semiconductor element includes an additional first electrode located on the opposite side in the first direction,
wherein the second wire is conductively joined to the additional first electrode and one of the two first suspension leads, and
wherein a shape of the second wire is different from a shape of the first wire.

13. The semiconductor device of claim 12, further comprising:
a first bump which is a conductor,
wherein the second wire includes a third connection portion conductively joined to one of the two first suspension leads, and
wherein the third connection portion is sandwiched between one of the two first suspension leads and the first bump.

14. The semiconductor device of claim 12, further comprising:
a sealing resin configured to cover the first die pad, the first semiconductor element, the first wire, and the second wire,
wherein the sealing resin has a first side surface facing a side on which the first intermediate lead is located with reference to the first die pad in the second direction, and
wherein each of the plurality of first leads and the two first suspension leads protrudes from the first side surface.

15. The semiconductor device of claim 14, wherein the sealing resin has two second side surfaces facing in different sides in the third direction, and
wherein each of the two first suspension leads is spaced apart from the two second side surfaces.

16. The semiconductor device of claim 15, wherein a gate mark is formed on each of the two second side surfaces,
wherein a surface roughness of the gate mark is greater than surface roughnesses of other regions of each of the two second side surfaces, and
wherein the gate mark formed on either of the two second side surfaces overlaps with the first side lead when viewed in the third direction.

17. The semiconductor device of claim 15, further comprising:
a second die pad located on a side of the first die pad opposite the first intermediate lead in the second direction;
a second semiconductor element mounted on the second die pad; and
an insulating element electrically conductive with each of the first semiconductor element and the second semiconductor element,
wherein the insulating element is of an inductively coupled type, and is mounted on the first mounting surface.

18. The semiconductor device of claim 17, further comprising:
a plurality of second leads, each of which is electrically conductive with the second semiconductor element,
wherein the sealing resin has a third side surface facing a side opposite the first side surface in the second direction, and
wherein each of the second leads protrudes from the third side surface.
